(19) United States
(12) Patent Application Publication
(10) Pub. No.: US 2010/0112807 A1
(43) Pub. Date: May 6, 2010

(54) METHOD OF FORMING METAL WIRING OF SEMICONDUCTOR DEVICE

(76) Inventor: Sang-Chul Kim, Eumseong-gun (KR)

Correspondence Address: SHERR & VAUGHN, PLLC, 620 HERNDON PARKWAY, SUITE 320, HERNDON, VA, 20170, US

(21) Appl. No.: 12/608,052

(22) Filed: Oct. 29, 2009

(30) Foreign Application Priority Data
Nov. 5, 2008 (KR) 10-2008-0109297

(51) Int. Cl. H01L 21/768; H01L 21/31

(52) U.S. Cl. 438/653; 438/778; 438/597; 257/E21.24; 257/E21.584

(57) ABSTRACT

A method of forming a metal wiring of a semiconductor device, and devices thereof. A method of forming a metal wiring, and devices thereof, may maximize semiconductor yield by substantially removing oxide on and/or over a trench and/or by substantially removing a by-product that may remain on and/or over a surface of a wafer. A method of forming a metal wiring of a semiconductor may include forming a dielectric layer on and/or over a metal wiring. A method of forming a metal wiring of a semiconductor may include forming a contact hole, which may expose a partial surface of metal wiring, on and/or over a dielectric layer. A method of forming a metal wiring of a semiconductor may include performing an oxide removing process on and/or over an inner side of a contact hole, and/or performing a by-product removing process on and/or over an inner side wall of a trench.

The present application claims priority under 35 U.S.C. 119 to Korean Patent Application No. 10-2008-0109297 (filed on Nov. 05, 2008) which is hereby incorporated by reference in its entirety.

### BACKGROUND

Embodiments relate to an electric device and methods thereof. Some embodiments relate to a method of forming metal wiring of a semiconductor device.

Copper wiring may be used for an interlayer connection of a semiconductor device. The formation of copper wiring may be performed by a damascene process. A damascene process may relate to a process of forming a wiring on and/or over a trench shape. A damascene process may include forming a trench on and/or over a dielectric layer through a photolithography and/or an etching process. A damascene process may include filling a trench with conductive material such as tungsten (W), aluminum (Al) and/or copper (Cu). A damascene process may include removing conductive material other than wiring, using for example an etch back method and/or a chemical mechanical polishing (CMP) method.

To substantially completely bury a trench, a conductive layer having a sufficient thickness may be deposited and a relatively thick conductive layer positioned on and/or over regions other than a trench may be polished through a CMP process in a damascene process. However, a dishing phenomenon may occur since a surface of a conductive layer within a trench may be sunken, for example concave, due to an excessive polishing and/or a relatively increased CMP process speed. Also, a scratch may be generated.

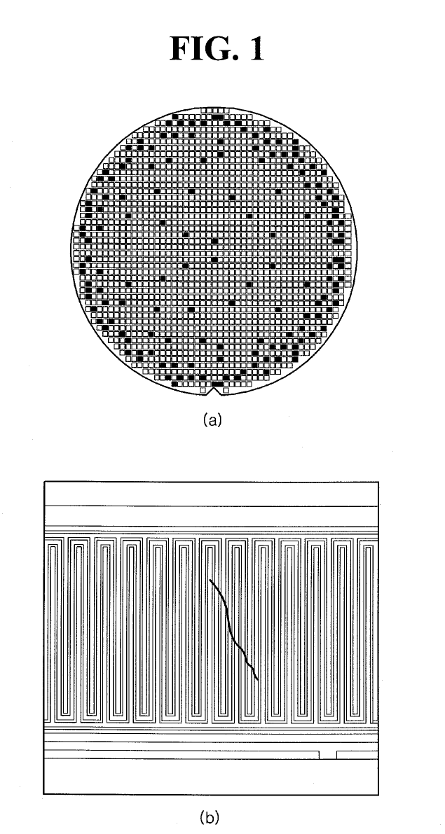

FIG. 1 illustrates a DM map and defects after a CMP process that may be performed in a damascene process. Substantially most defects may exist at edge regions of a wafer, as illustrates in FIG. 1 (a), and/or defects may be concentratedly generated from a top layer. A top layer may be substantially different from an inner-layer and/or inter-layer. The difference may result from a type of dielectric layer, for example TEOS, FSG/USG, etc., a thickness and/or a method of forming a dual damascene.

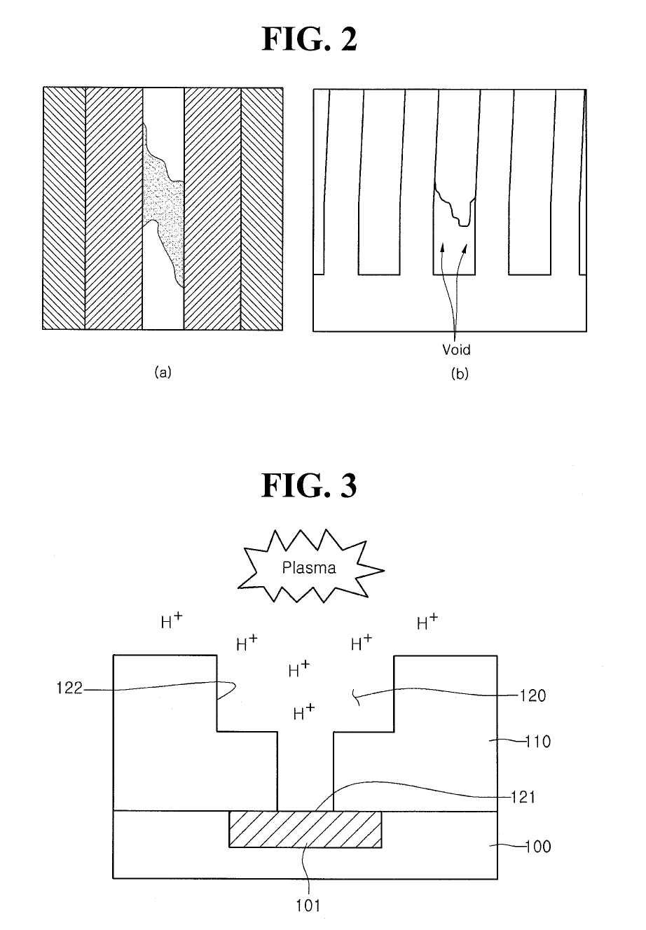

FIG. 2 (a) and FIG. 2 (b) illustrate a front image and a side image of a device. Although defects appear to be similar to a CMP scratch, they are different. A CMP scratch may exist on and/or over both a dielectric layer and a metal wiring, while defects of a linear copper (Cu) that may be concentratedly missing may exist on and/or over metal wiring. As illustrated in FIG. 2 (b), such a defect may be different than a CMP scratch and may include a void at a side wall of a trench.

Accordingly, there is a need for a method of forming a metal wiring of a semiconductor device, and devices thereof, which may maximize semiconductor yield. There is also a need for a method of forming a metal wiring of a semiconductor device, and devices thereof, which may substantially remove an oxide that may be generated at a lower side on and/or over a trench and/or a by-product that may remain on and/or over a surface of a wafer.

### SUMMARY

Embodiments relate to a method of forming a metal wiring of a semiconductor device, and devices thereof. According to embodiments, a method of forming a metal wiring may maximize semiconductor yield. In embodiments, a method of forming a metal wiring of a semiconductor device may substantially removing oxide on and/or over a trench, and/or a by-product that may remain on and/or over a surface of a wafer.

According to embodiments, a method of forming a metal wiring of a semiconductor device may include forming a dielectric layer on and/or over metal wiring. In embodiments, a method of forming a metal wiring of a semiconductor device may include forming a contact hole, which may expose a partial surface of metal wiring, on and/or over a dielectric layer. In embodiments, a method of forming a metal wiring of a semiconductor device may include performing an oxide removing process on and/or over an inner side of a contact hole.

According to embodiments, a method of forming a metal wiring of a semiconductor device may include forming a dielectric layer on and/or over a lower metal wiring. In embodiments, a method of forming a metal wiring of a semiconductor device may include forming a trench, which may expose a partial surface of a lower metal wiring, on and/or over a dielectric layer. In embodiments, a method of forming a metal wiring of a semiconductor device may include performing a by-product removing process on and/or over an inner side wall of a trench. In embodiments, a method of forming a metal wiring of a semiconductor device may include forming a diffusion barrier layer on and/or over a trench.

According to embodiments, a method for forming a metal wiring of a semiconductor device may include forming a dielectric layer on and/or over a substrate in which a lower metal wiring may be formed. In embodiments, a method of forming a metal wiring of a semiconductor device may include forming a trench by partially etching a dielectric layer. In embodiments, a method of forming a metal wiring of a semiconductor device may include performing a plasma treatment on and/or over a trench. In embodiments, a method of forming a metal wiring of a semiconductor device may include forming an upper metal wiring on and/or over a trench.

According to embodiments, a method of forming a metal wiring of a semiconductor device may include a hydrogen plasma treatment process. In embodiments a hydrogen plasma treatment process may include a foreign material removing process which may form plasma using H₂ gas, He gas and/or Ar gas, and/or which may use excited H+ ions.

According to embodiments, a method of forming a metal wiring and devices thereof may maximize characteristics of a device. In embodiments, a method of forming a metal wiring may relatively effectively remove Cu-Oxide on and/or over a lower portion of a trench, and/or a by-product remaining on and/or over a surface of a wafer, for example by performing a hydrogen plasma treatment on and/or over a substrate after a damascene pattern.

### DRAWINGS

Example FIG. 1 is a diagram and an image illustrating a defect map of a missing linear copper.

Example FIG. 2 is a plan view and a cross-sectional view illustrating the defect described in FIG. 1.

Example FIG. 3 to FIG. 5 are cross-sectional views illustrating a method of forming a metal wiring of a semiconductor device in accordance with embodiments.

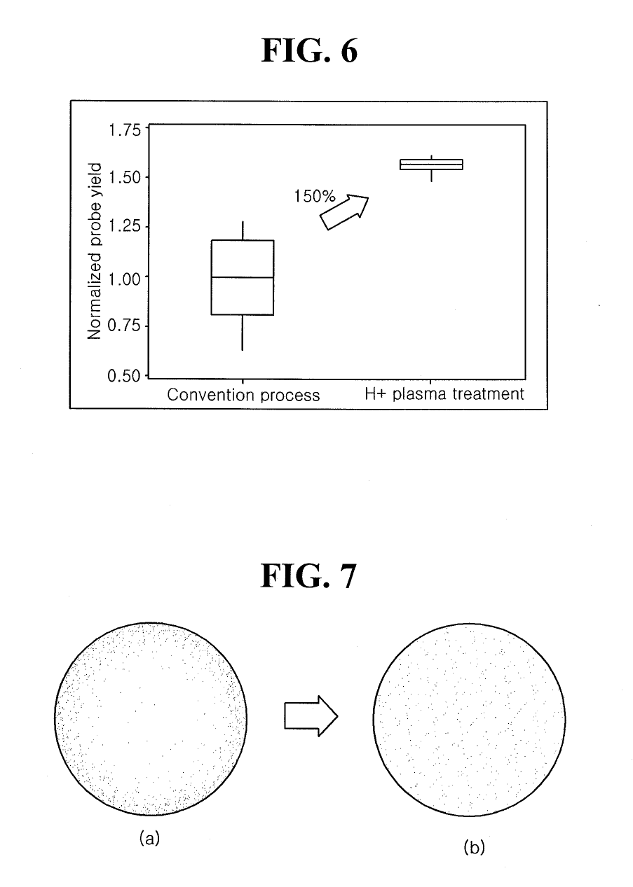

Example FIG. 6 is a graph comparing yield of a semiconductor device and yield of a semiconductor device fabricated in accordance with embodiments.

Example FIG. 7 is a diagram comparing regions where defects are generated in a semiconductor device to a semiconductor device fabricated in accordance with embodiments.

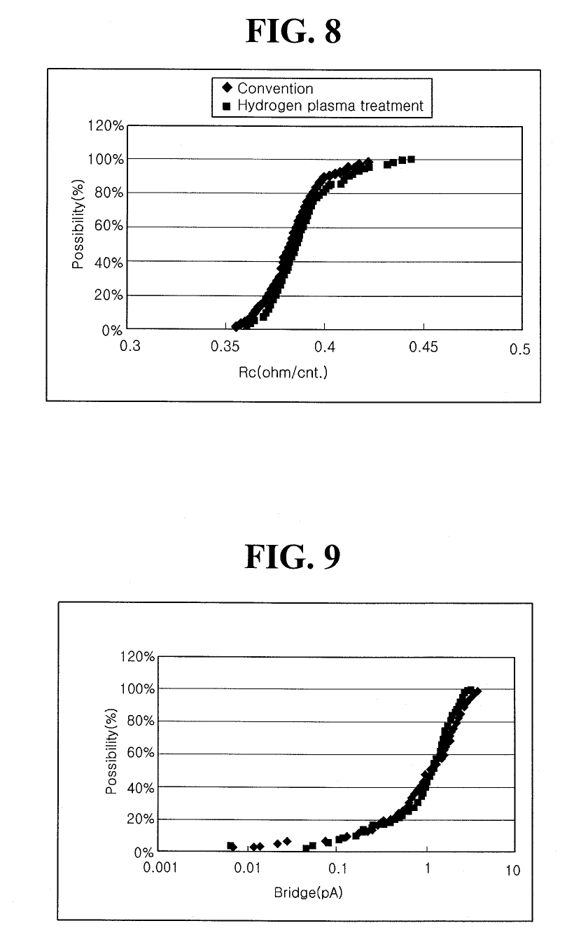

Example FIG. 8 to FIG. 9 are graphs comparing electrical characteristics of a semiconductor device to a semiconductor device fabricated in accordance with embodiments.

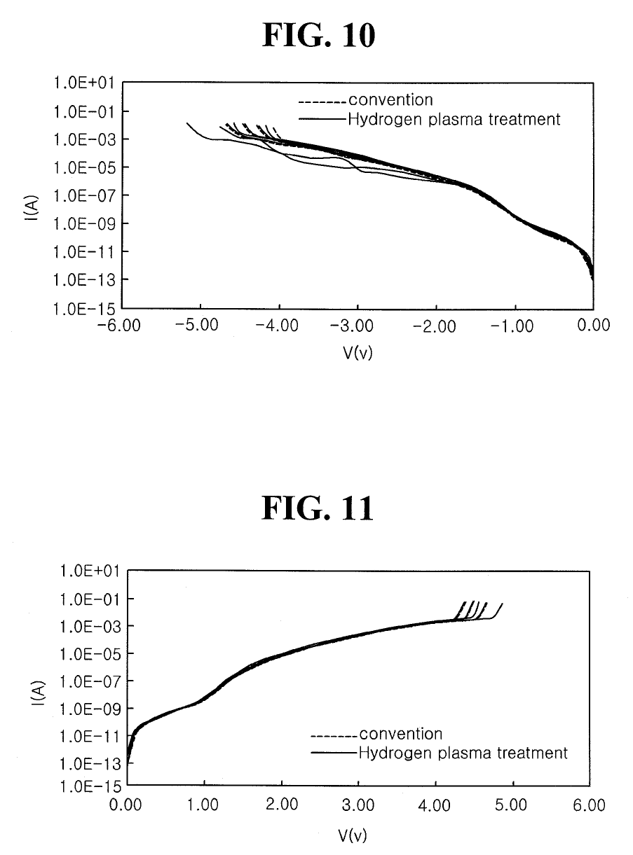

Example FIG. 10 to FIG. 11 are graphs comparing a hydrogen plasma treatment process that is not performed on Vramp of a gate oxide to a hydrogen plasma treatment process performed in accordance with embodiments.

### DESCRIPTION

Embodiments relate to a method for forming a metal wiring of a semiconductor device. Referring to example FIG. 3 to FIG. 5, cross-sectional views illustrate a method of forming a metal wiring of a semiconductor device. Referring to FIG. 3, copper (Cu) may be deposited on and/or over a semiconductor substrate 100. In embodiments, a semiconductor substrate may include silicon, silicon on insulator (SOI), germanium and/or other semiconductor materials. Accordingly, embodiments include devices fabricated using one or more semiconductor materials and/or technologies such as thin-film-transistor (TFT) technology using polysilicon on and/or over glass substrates.

According to embodiments, copper (Cu) deposition may include an ion beam, an electronic beam and/or a RF sputtering method. In embodiments, copper (Cu) may be etched using a photoresist pattern to forming lower metal wiring 101. In embodiments, dielectric layer 110 may be formed, for example over semiconductor substrate 100 and/or lower metal wiring 101. In embodiments, dielectric layer 110 may be formed of oxide and/or nitride, for example, SiO₂. In embodiments, a photoresist pattern may be formed on and/or over dielectric layer 110, and dielectric layer 110 may be selectively removed using a pattern. In embodiments, a trench 120 may be formed which may expose a portion of lower metal wiring 101.

According to embodiments, a damascene process may be applied. In embodiments, a process of removing foreign material and/or oxide may also be applied after a contact hole and/or a via hole is formed. In embodiments, a hydrogen plasma treatment process may be performed as a process to remove a Cu-Oxide that may be generated at a lower side on and/or over trench 120 and/or a by-product that may remain on and/or over a surface of a wafer. When a metal wiring intended to form within trench 120 may include a metal wiring on and/or over a top layer, Cu-Oxide may be formed on and/or over lower bottom 121 of trench 120. Also, a by-product may remain at partial side walls of trench 120. In embodiments, a hydrogen plasma treatment process may be performed to remove foreign materials. In embodiments, a hydrogen plasma treatment process may form plasma using H₂ gas and/or inert gas such as He, Ar, etc. In embodiments, foreign materials may be physically removed at a lower end and/or side walls of a trench, for example using excited H+ ions.

According to embodiments, a hydrogen plasma treatment process may include a process to substantially remove Cu-Oxide formed on and/or over lower bottom 121 of a trench, which may be an upper surface of lower metal wiring 101. In embodiments, a hydrogen plasma treatment process may include a process to remove Cu-Oxide using excited hydrogen ions. In embodiments, a hydrogen plasma treatment process may relate to an oxide removing process for a lower metal wiring. In embodiments, substantial removal of a by-product generated at side walls 122 of trench 120 may also be performed by a hydrogen plasma treatment process. In embodiments, a hydrogen plasma treatment process may relate to a by-product removing process for a trench and/or a contact hole.

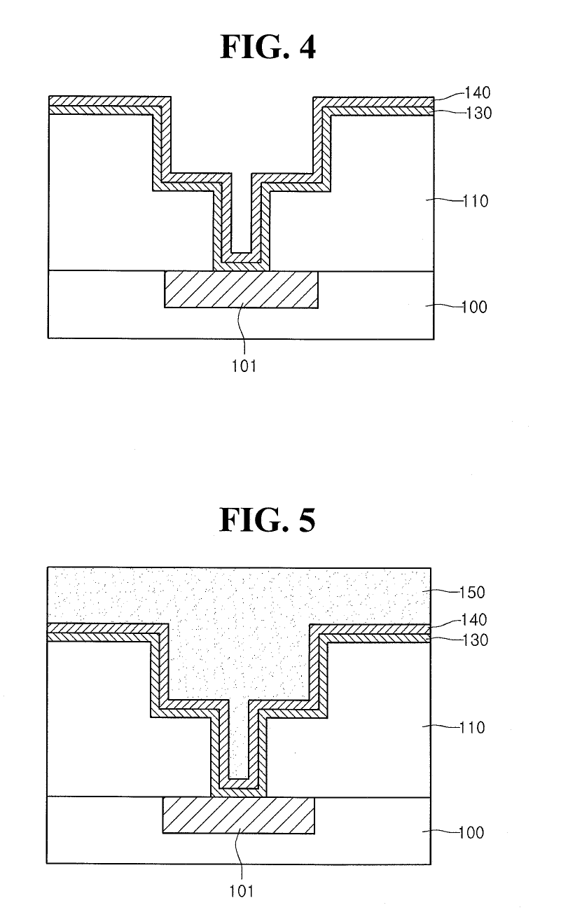

Referring to FIG. 4, diffusion barrier layer 130 and/or copper seed layer 140 may be deposited, for example sequentially, on and/or over trench 120. According to embodiments, an electrolyte may be added after diffusion barrier layer 130 and/or copper seed layer 140 may be formed within trench 120. In embodiments, an electrolyte used in an ECP process, which may include an additive to suppress formation of a void and/or a seam during a copper gap-fill process, may include organic material components such as an accelerator, a suppressor and/or a lever. In embodiments, an organic additive may exist within a electrolyte such that a bottom-up fill may be expedited.

Referring to FIG. 5, an upper surface of a copper metal may be planarized through a CMP process after copper metal may be formed within a trench, using for example copper seed layer 140. In embodiments, upper metal wiring 150 may be formed, for example as illustrated. In embodiments, a hydrogen plasma treatment process may be performed as a process to remove foreign material generated within a trench. In embodiments, a semiconductor device fabricated in accordance with embodiments may exhibit maximized characteristics.

Referring to example FIG. 6 to FIG. 7, diagrams illustrate a comparison of yield of a semiconductor device where a hydrogen plasma treatment process is performed to a semiconductor device where a hydrogen plasma treatment process is not performed. According to embodiments, a defect distribution of a wafer may be substantially uniformly formed as a result of performing a hydrogen plasma treatment, as illustrated in FIG. 7, and/or a number of such defects may be relatively significantly reduced. In embodiments, a defect rate of a wafer edge may be relatively significantly reduced, and/or a wafer yield may be substantially abruptly raised, for example from approximately 50% to 70% as illustrated in FIG. 6.

Referring to example FIG. 8 and FIG. 9, graphs illustrate a comparison of electrical characteristics of a semiconductor device to a semiconductor device fabricated in accordance with embodiments. In embodiments, a hydrogen plasma treatment may not substantially adversely affect electrical characteristics of a device, such as sheet resistance, chain resistance and/or leakage current. In embodiments, although a hydrogen plasma treatment may be performed on and/or over an inside of a trench and/or a semiconductor substrate before a diffusion barrier layer may be formed, electrical characteristics such as chain resistance and/or leakage current, illustrated respectively in FIG. 8 and FIG. 9, may be substantially similar to when a hydrogen plasma treatment is not performed.

Referring to example FIG. 10 and FIG. 11, graphs illustrate a comparison of a hydrogen plasma treatment process that is not performed on Vramp of a gate oxide to a hydrogen plasma treatment process performed in accordance with embodiments. Referring to FIG. 10, a comparative graph for nMOS is illustrated, and referring to FIG. 11, a comparative graph for pMOS is illustrated. Although an antenna effect of a semiconductor device may be a concern using a hydrogen plasma treatment process, there is no substantial change in characteristics of a transistor in accordance with embodiments. As illustrated from the comparative results, although a hydrogen plasma treatment is performed to remove foreign material generated inside a trench, yield of a semiconductor device may be maximized, and/or characteristics of a semiconductor device may not be substantially adversely affected.

According to embodiments, a hydrogen plasma treatment may be performed before a diffusion barrier layer may be deposited and may serve to substantially remove Cu-Oxide on and/or over a lower portion of a trench. In embodiments, a hydrogen plasma treatment may clean impurity generated on and/or over a surface of a silicon oxide layer. In embodiments, a hydrogen plasma treatment may be relatively effective to remove polymer-based by-products which may deteriorate adhesion between a silicon oxide layer and a diffusion barrier layer. In embodiments, a hydrogen plasma treatment may be relatively effective to substantially prevent Cu missing.

According to embodiments, yield of a semiconductor device may be maximized by addressing linear Cu missing and/or substantially preventing generation thereof. Cu missing may be generated from a top copper wiring of a Cu FCT device, for example, and may be generated concentratedly on and/or over an edge region of a wafer. Such a defect may reduce yield of a device by shorting a wiring, which may include a killing defect having a kill-ratio of approximately 50% or more. In embodiments, a hydrogen plasma treatment performed, for example prior to depositing a diffusion barrier layer, may be relatively effective to address these problems. Also, insufficient adhesion between a surface of a dielectric layer and a diffusion barrier layer may be a cause of Cu-missing. However, in embodiments, a fail-rate of a wafer edge may be minimized through a hydrogen-plasma treatment, and/or a wafer yield may be maximized, for example raised by approximately 30%.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a dielectric layer over metal wiring;
forming a contact hole exposing at least a partial surface of said metal wiring; and
performing an oxide removing process over an inner side of said contact hole.

2. The method of claim 1, wherein said oxide removing process comprises a hydrogen plasma treatment process including excited hydrogen ions.

3. The method of claim 2, wherein said hydrogen plasma treatment process is performed over said exposed surface of said metal wiring and a side wall of said contact hole.

4. The method of claim 2, wherein said hydrogen plasma treatment process comprises plasma formed including at least one of H₂ gas, He gas and Ar gas.

5. The method of claim 1, wherein:
said metal wiring is formed of copper;
a Cu-Oxide is formed over said exposed surface of said metal wiring; and
said hydrogen plasma treatment process includes excited hydrogen ions and substantially removes said Cu-Oxide.

6. The method of claim 1, wherein said metal wiring is formed over a semiconductor substrate.

7. The method of claim 6, wherein said semiconductor substrate comprises at least one of silicon, silicon on insulator and germanium.

8. A method comprising:
forming a dielectric layer over a lower metal wiring;
forming a trench exposing a partial surface of said lower metal wiring;
performing a by-product removing process over an inner side wall of the trench; and
forming a diffusion barrier layer over the trench.

9. The method of claim 8, wherein performing said by-product removing process comprises a hydrogen plasma treatment process including excited hydrogen ions.

10. The method of claim 9, wherein said hydrogen plasma treatment process comprises plasma formed including at least one of H₂ gas, He gas and Ar gas.

11. The method of claim 8, wherein performing said by-product removing process comprises performing a plasma treatment over said side wall of the trench and a lower bottom of the trench.

12. The method of claim 8, wherein said metal wiring is formed over a semiconductor substrate.

13. The method of claim 12, wherein said semiconductor substrate comprises at least one of silicon, silicon on insulator and germanium.

14. A method comprising:
forming a dielectric layer over a substrate including a lower metal wiring;
forming a trench by partially etching said dielectric layer;
performing a plasma treatment over an inside of the trench; and
forming an upper metal wiring over the trench.

15. The method of claim 14, wherein said plasma treatment comprises a hydrogen plasma treatment process including excited hydrogen ions.

16. The method of claim 15, wherein said hydrogen plasma treatment process comprises plasma formed including at least one of H₂ gas, He gas and Ar gas.

17. The method of claim 15, wherein a diffusion barrier layer is formed over said dielectric layer over the trench after said hydrogen plasma treatment process is performed.

18. The method of claim 14, wherein:
the trench is formed such that a partial upper surface of said lower metal wiring is exposed; and
said hydrogen plasma treatment is performed over said lower metal wiring over the trench to remove an oxide formed over said upper surface.

19. The method of claim 14, wherein said substrate comprises a semiconductor substrate.

20. The method of claim 19, wherein said semiconductor substrate comprises at least one of silicon, silicon on insulator and germanium.
